(19) United States
(12) Patent Application Publication
(10) Pub. No.: US 2002/0192932 A1
(43) Pub. Date: Dec. 19, 2002

(54) Salicide integration process

(75) Inventors: Chao-Chieh Tsai, Taichung (TW); Chia-Shiung Tsai, Hsin-Chu (TW); Shi-Chung Sun, Taipei (TW); Shou-Gwo Wuu, Chu-Tong (TW)

Correspondence Address: George O. Saile, 20 McIntosh Drive, Poughkeepsie, NY, 12603, US

(73) Assignee: TAIWAN SEMICONDUCTOR MANUFACTURING COMPANY

(21) Appl. No.: 10/042,419

(22) Filed: Jan. 9, 2002

Related U.S. Application Data
(62) Division of application No. 09/857,966, filed on Jun. 13, 2001.

(51) Int. Cl. H01L 21/3205

(52) U.S. Cl. 438/592

(57) ABSTRACT

A method is disclosed for forming multilayered self-aligned gate electrodes having uniform silicide layer. It is shown that by using amorphous silicon of a certain thickness with or without polysilicon as an underlayer material, the salicide structure so formed has improved gate characteristics.

### BACKGROUND OF THE INVENTION

(1) Field of the Invention

The present invention relates to manufacturing of semiconductor devices in general, and in particular, to the integration of a stacked salicide process for forming gate electrodes in MOSFET devices.

(2) Description of the Related Art

A typical Metal Oxide Semiconductor Field Effect Transistor (MOSFET) device comprises, as is shown in the well known structure of FIG. 1, a gate (40) formed on an insulator oxide (30) which in turn is formed on a silicon substrate (10) having source/drain regions (20) delineated by field oxide regions (50). The surface area of the substrate between the source/drain regions (20) is called a channel region (45). The device becomes operational when a voltage V_{g}, larger than a threshold voltage, Vₜₕ, is impressed on gate (40) through a conductive path (55) such that current flows between source and drain regions (20) through channel (15). The source and drain are also connected by means of their own conductive paths (67) to complete the integrated circuit. The conductive paths are interconnections that are fabricated by depositing metal into holes that are formed in interlevel dielectric layer (60) as shown in FIG. 1. The physical structure as well as the concomitant electrical characteristics of the gate electrode (40) has a controlling effect on the operation of the device.

The forming of the gate structure is usually complex and requires exacting processes. Furthermore, materials used for the gate must be compatible with processes that follow up to the completion of the manufacture of the semiconductor devices. With the advent of ULSI (ultra large scale integration) of devices, the shrinking dimensions of the gate as well as the materials used to form the gates have gained even more significance. Thus, if aluminum were to be used as the gate material for example, then, because of its low melting point, it would have to be deposited following the completion of all high-temperature process steps, including drive-in of the source and drain regions, To form the gate electrode in proper relationship to the source/drain, it must be separately aligned with respect to the source and drain. This alignment process adversely affects both packing density and parasitic overlay capacitances between the gate and source/drain regions. For these reasons, it has become a recent practice to use polycrystalline silicon (poly-Si), which has the same high melting point as the silicon substrate, as the gate material. Hence, polysilicon can now be deposited over the gate to form the gate electrode prior to the source and drain formation. Consequently, the gate itself can serve as a mask during formation of the source and drain regions by either diffusion or ion implantation, as is known in the art. Gate (40) thereby becomes nearly perfectly aligned over channel (45) and with respect to source/drain (20) shown in FIG. 1. The only overlap of the source and drain is due to lateral diffusion of the dopant atoms. This self-alignment feature simplifies the fabrication sequence, increases packing density, and reduces the gate-source and gate-drain parasitic overlap capacitances. For completeness, we note that the threshold voltage, Vₜₕ, of MOS device is also favorably affected by the use of polysilicon as the gate electrode material.

On the other hand, polysilicon has much higher electrical resistance as compared to aluminum, for example, and the miniaturization of devices in the ULSI era has exacerbated the electrical properties of the poly-Si gate electrode. Polysilicon is commonly doped by ion implantation to lower the resistivity substantially. However, according to Wolf in his book “Silicon Processing for the VLSI Era,” vol. 1, Lattice Press, Sunset Beach, Calif., 1986, pp. 176-77″, even at the highest dopant concentrations, a 0.5 micrometer (μm)-thick polysilicon film has a sheet resistance of about 20 Ω/sq which is about two orders of magnitude larger than that of aluminum film of the same thickness. The resulting high values of line resistance can lead to long propagation delays and severe dc voltage variations within an ULSI circuit.

In order to overcome the high resistivity problem encountered with polysilicon alone, polycides, a multilayer structure comprising polysilicon (42) and metal silicides (44), are used to form gate electrodes (40) such as depicted in FIG. 1. Silicides are a group of refractory metal compounds (MSiₓ) that are formed by basically three techniques, each of which involves deposition followed by a thermal step to form the silicide: 1. deposition of a pure metal such as tungsten (W), titanium (Ti) or Molybdenum (Mo) on polysilicon, 2. simultaneous evaporation of the silicon and the refractory metal from two sources, and 3. sputter-depositing the silicide itself from a composite target, or by co-sputtering or layering. However, the physical structure of the underlying polysilicon layer plays an important role in determining the effectiveness of the top silicide layer in reducing the sheet resistivity of the layered composite gate electrode so formed.

Normally, the topography of the polysilicon layer is quite non-uniform and irregular with globular large grains forming at the outer boundary of the film surface. This in turn causes irregularities in the formation of the silicide layer thereon. Recent experience has shown that the uniformity of silicidation over the polysilicon layer is important in obtaining low overall sheet resistivity of the multilayered structure. A novel method for improving the uniformity of silicidation and hence, reducing resistivity is disclosed later in the embodiments of this invention. When this method is integrated with self-aligned silicide process, called salicide, the resistivity of sub-half-micron gate electrodes are further reduced as disclosed in this invention.

In a salicide process, after the polysilicon layer (42) has been deposited and patterned following conventional lithographic and etching methods, sidewall spacers (75) are formed. This is accomplished by depositing a layer of oxide (not shown) which conformally covers the polysilicon layer (42). The oxide layer is then etched back anisotropically until the polysilicon layer is exposed. Unetched portions of the oxide at the vertical sides of the poly-Si remain following this etch. These residual structures then form the oxide spacers (75) shown in FIG. 1. As is well known in the art, the purpose of the spacers is to prevent shorting between metal deposited subsequently on the gate and on the source/drain regions. The metal used to form the silicide (44) is deposited. Substrate (10) is next heated, which causes the silicide reaction to occur wherever the metal is in contact with the silicon. Everywhere else, the metal remains untreated. The unreacted metal at places such as over the spacers is selectively removed through the use of an etchant that does not attack the silicide, the silicon substrate, or the oxide. As a result, in addition to the polysilicon layer (42), only each exposed source and region is now completely covered by silicide film (not shown) but no other place. It will be noted that the resulting multilayered polycide film over the gate comprising polysilicon and silicide has been self-aligned with respect to the source/drain regions and is therefore, a salicide. A dielectric layer is next deposited onto the salicide, and holes are opened in it down to the salicide layer. Metal is deposited into the holes to make contact with the salicide. The topography of the surface of the polysilicon layer in the multilayered salicide structure determines the electrical characteristics of the so formed gate electrode.

The effect of the topography of the grains on the resistivity of the polysilicon film can be understood following the model described in Wolf “Silicon Processing for the VLSI Era,” vol. 1, Lattice Press, Sunset Beach, Calif., 1986, pp. 176-77″. However, it is not necessary to describe it here in detail to understand the present invention. It is sufficient to note that according to the model, the behavior of poly-Si resistivity is a function of the grain size, among other things. It will be seen later that the method of this invention improves the topography of the grains at the interface between the poly-Si and the silicide layers of the multilayer gate electrode.

In a method disclosed in U.S. Pat. No. 5,554,566 Lur also manipulates the surface topography of polysilicon, but differently, to improve its adhesion to the metal silicide. Here, the polysilicon layer is treated in either phosphoric aid or by anodization in hydrofluoric acid to obtain hemispherical grained surface. In another patent, Wang teaches in U.S. Pat. No. 5,508,212 a salicide process for manufacturing a lightly doped drain MOS transistor having unshorted titanium silicide gate electrode and source/drain contacts. However, neither one of these prior art addresses the problem of high resistivity encountered with salicides that use self-alignment process with suicides. What is needed, therefore, is a method where salicide process can be integrated with a process for improving the uniformity of silicidation.

### SUMMARY OF THE INVENTION

It is therefore an object of this invention to provide a new method of forming gate electrode for semiconductor devices.

It is another object of this invention to provide a method for fabricating gate electrode with an integrated salicide process.

It is still another object of this invention to provide a method of improving the uniformity of silicide formation in a multilayered gate electrode of a semiconductor device.

It is yet another object of this invention to provide a multilayer gate electrode structure having uniform silicide layer formed on an amorphous silicon layer.

These objects are accomplished by providing a substrate with gate oxide formed on a substrate having source/drain regions delineated by field oxide regions; depositing undoped polycrystalline silicon (poly-Si) over said substrate followed by deposition of a layer of amorphous silicon (A-Si); forming oxide spacers; depositing refractory metal and forming a silicide layer by means of a salicide process. In another embodiment, the gate electrode is formed of A-Si and silicide.

These objects are accomplished also by providing a multilayer structure comprising poly-Si, a-Si and silicide to form a new salicide to form a gate electrode of a semiconductor device.

### BRIEF DESCRIPTION OF THE DRAWINGS

In the accompanying drawings, similar numerals refer to similar parts throughout-the several views.

FIG. 1 is a partial cross-sectional views of a semiconductor substrate showing the steps of forming conventional gate electrode.

FIGS. 2a-2b are partial cross-sectional views of a semiconductor substrate showing the forming of a multilayered gate electrode structure comprising polycrystalline silicon, amorphous silicon and a uniform layer of silicide.

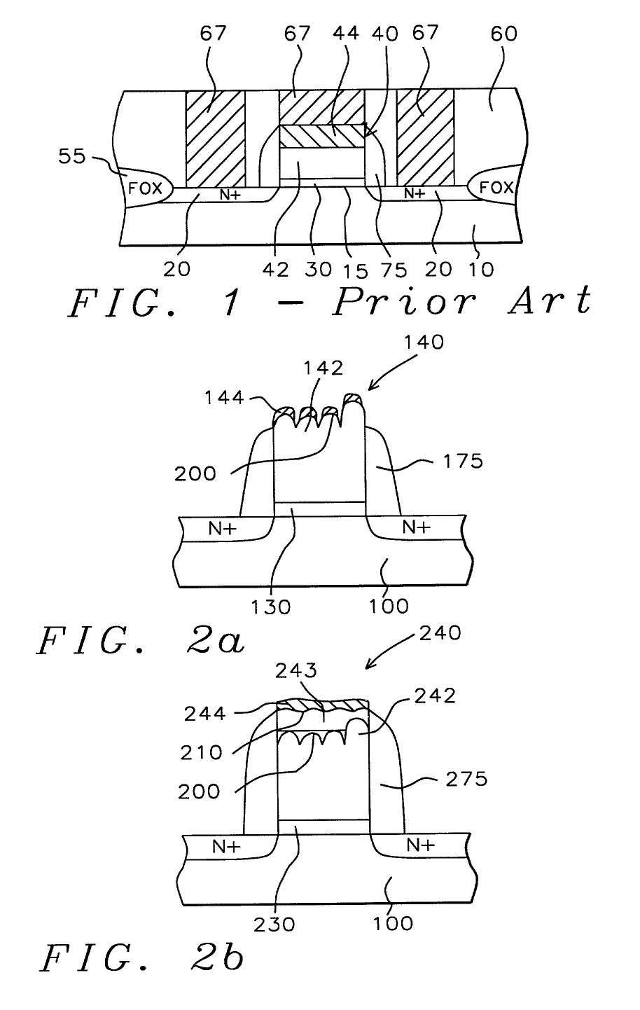

### DESCRIPTION OF THE PREFERRED EMBODIMENTS

Referring now to the drawings, in particular to FIGS. 2a and 2b, there are shown schematically gate electrodes formed on a substrate. In FIG. 2a, gate oxide (130) is formed on the surface of semiconductor substrate (100). The gate oxide has a thickness in between about 45 to 130 angstroms (Å). Polysilicon (poly-Si) layer (142) is next formed on gate oxide (130) with a thickness between about 2000 to 3000 Å. Poly-Si layer (142) is then patterned into a gate electrode (140) having vertical sidewalls and a top surface.

Using Poly-Si gate (142) as a mask, source/drain regions are next formed by ion implantation. It is preferred that the ions are phosphorous and are implanted at a dose between about 1.0×10¹³ to 5.0×10¹³ atoms/cm² and at an energy between about 20 to 40 Kev.

Subsequently, an insulating dielectric layer (not shown) is deposited on the substrate, thereby completely encapsulating the Poly-Si gate (142). This can be accomplished by forming a silicon dioxide layer using chemical vapor deposition process. The dielectric layer is then etched back anisotropically until Poly-Si layer is exposed and oxide spacers (175) are formed on the sidewalls of the gate electrode. It has been observed that with the present process, grain boundaries of the exposed Poly-Si layer are globular and non-uniform as depicted in FIG. 2a. When in the next step a silicide layer (144) is deposited, the resulting silicide layer is also globular and nonuniform as shown in the same Figure. This has resulted in unacceptably high sheet resistivity and narrow line effect for gate widths between about 0.3 to 0.4 micrometers.

It is, therefore, a main feature and key spirit of the present invention that following the step of depositing polycrystalline silicon, a layer of amorphous silicon (A-Si) be deposited prior to the formation of oxide spacers. This is because, A-Si with a preferred thickness between about 200 to 400 Å forms grain boundaries (210) which are much less globular compared to the grain boundaries (200) of the Poly-Si layer shown in FIG. 2b.

Referring now to FIG. 2b, there is shown a preferred embodiment where a substrate having a Poly-Si layer, is additionally covered with A-Si layer forming a Poly-Si/A-Si gate having a total thickness between about 2000 to 3000 Å. The process steps following the formation of this Poly-Si/A-Si gate are those that are specified above, namely: Poly-Si/A-Si layers (242) (243) are then patterned into gate electrode (240) having vertical sidewalls and a top surface. Using Poly-Si/A-Si gate (240) as a mask, source/drain regions are next formed by ion implantation. Subsequently, an insulating dielectric layer (not shown) is deposited on the substrate, thereby completely encapsulating the Poly-Si/A-Si gate (240). This can be accomplished by forming a silicon dioxide layer using chemical vapor deposition process. The dielectric layer is then etched back anisotropically until A-Si layer (243) is exposed and oxide spacers (275) are formed on the sidewalls of the gate electrode (240) as shown in FIG. 2b. Oxide spacers serve as a separation mask for forming silicide layer (244) in a selective and self-aligning manner on the surface of the gate electrode (240) and the surface of the doped source/drain regions not shown in FIG. 2b. It is preferred that the oxide spacers have a thickness between about 800 to 1500 Å.

It is preferred that the silicide comprises titanium forming TiSi having a thickness between about 200 to 500 Å. It is also preferred that titanium is thermally annealed to form a silicide at a temperature range between about 700 to 750° C. for a duration of between about 10 to 40 seconds. A reaction is generated in the regions of the titanium layer (244) in contact with the silicon layer on the surface of the silicon substrate (100) and the amorphous silicon layer on the surface of the gate electrode (240) through the heat treatment to form titanium silicide layer (244). It will be understood, however, that other methods of silicide deposition can also be used without departing from the spirit and scope of the invention. These include the simultaneous evaporation of silicon and a refractory metal from two sources, and sputter-depositing the silicide, either form a composite target, or by co-sputtering or layering. After the forming of the silicide, portions thereof that remain unreacted are selectively removed by means of an etchant that does not attack the silicide, the silicon substrate, or the oxide spacers. The preferred etchant is NH₄OH:H₂O₂:H₂O ::1:1:1 at between about 23 to 27° C.

The salicide integration process that is disclosed in this invention has the advantage of providing a uniform silicide layer which in turn suppresses narrow line effect. At the same time, this improved uniformity of silicidation yields lower sheet resistivity which is key in extending the use of polysilicon structures as gate electrodes to the ever shrinking devices of the ULSI technology.

In the descriptions of the embodiments given above, numerous details were set forth, such as specific materials, process parameter, etc., in order to provide a thorough understanding of the present invention. It will be obvious, however, to those skilled in the art that these specific details need not be employed to practice the present invention.

That is to say, while the invention has been particularly shown and described with reference to the preferred embodiments thereof, it will be understood by those skilled in the art that various changes in form and details may be made without departing from the spirit and scope of the invention.

What is claimed is:

1. A method of forming a gate electrode for a semiconductor device comprising the steps of:
providing a substrate having gate oxide layer over device regions formed therein;
depositing a layer of amorphous silicon on said gate oxide layer;
patterning said layer of amorphous silicon to form a gate electrode;
depositing a metal to form a silicide on said gate electrode; and
selectively removing said silicide to form a two-level salicide gate electrode.

2. The method of claim 1, wherein said amorphous silicon has a thickness between about 200 to 400 Å.

3. A method of forming a gate electrode for a semiconductor device comprising the steps of:
providing a substrate having gate oxide layer over device regions formed therein;
depositing a layer of polycrystalline silicon (poly-Si) on said gate oxide;
depositing a layer of amorphous silicon (A-Si) on said poly-Si to form a composite structure;
patterning said composite structure to form a gate electrode;
depositing a metal to form a silicide on said gate electrode; and
selectively removing said silicide to form a tri-level salicide gate electrode.

4. The method of claim 3, wherein the thickness of said Poly-Si is between about 1800 to 3000 Å.

5. The method of claim 3, wherein the thickness of said A-Si is between about 200 to 400 Å.

6. The method of claim 3, wherein the thickness of said silicide is between about 300 to 800 Å.

7. A method of forming a gate electrode for a semiconductor device comprising the steps of:
providing a substrate having gate oxide layer over device regions formed therein;
depositing a layer of polycrystalline silicon (Poly-Si) on said gate oxide;
depositing a layer of amorphous silicon (A-Si) on said polycrystalline silicon to form a composite structure;
patterning said composite structure to form a gate electrode;
forming oxide spacers adjacent to said gate electrode;
depositing a metal to form a silicide on said gate electrode; and
selectively removing said silicide to form a multilayered salicide gate electrode.

8. The method of claim 7, wherein said poly-Si is formed by chemical vapor deposition at a temperature between about 600 to 680° C.

9. The method of claim 7, wherein the thickness of said Poly-Si is between about 1800 to 2000 Å.

10. The method of claim 7, wherein said A-Si is formed by chemical vapor deposition at a temperature between about 525 to 560° C.

11. The method of claim 7, wherein the thickness of said A-Si is between about 200 to 400 Å.

12. The method of claim 7, wherein said composite structure is patterned by using etchant NH₄OH:H₂ O₂ :H₂O:1:1:1 at a temperature between about 23 to 27° C.

13. The method of claim 7, wherein said oxide spacers have thickness between about 800 to 1500 Å.

14. The method of claim 7, wherein said metal to form said silicide is titanium.

15. The method of claim 14, wherein said titanium is formed by physical vapor deposition at a temperature between about 100 to 500° C.

16. The method of claim 14, wherein the thickness of said titanium is between about 200 to 500 Å.

17. The method of claim 7, wherein said selective removal of said silicide is accomplished by means of etchant NH₄OH:H₂O₂:H₂O ::1:1:1 at a temperature between about 23 to 27° C.

18. A salicide structure comprising:
providing a substrate having gate oxide layer over device regions formed therein; and
a gate electrode having a polycrystalline silicon, amorphous silicon and silicide multilayers.

19. The structure of claim 18, wherein said gate electrode having said polycrystalline silicon, amorphous silicon and silicide multilayers is of thickness between about 2000 to 3000 Å.

20. A salicide structure comprising:
providing a substrate having gate oxide layer over device regions formed therein; and
a gate electrode having an amorphous silicon and silicide multilayers.

21. The structure of claim 20, wherein said gate electrode having said amorphous silicon and silicide multilayers is of thickness between about 2000 to 3000 Å.
